(19) United States
(12) Patent Application Publication
(10) Pub. No.: US 2023/0042793 A1
(43) Pub. Date: Feb. 9, 2023

(54) SEMICONDUCTOR STRUCTURE AND METHOD FOR MANUFACTURING SAME

(71) Applicant: CHANGXIN MEMORY TECHNOLOGIES, INC., Hefei City (CN)

(72) Inventors: TIEH-CHIANG WU, Hefei (CN); Lingxin ZHU, Hefei (CN)

(21) Appl. No.: 17/871,022

(22) Filed: Jul. 22, 2022

Related U.S. Application Data
(63) Continuation of application No. PCT/CN2022/071855, filed on Jan. 13, 2022.

(30) Foreign Application Priority Data
Aug. 9, 2021 (CN) 202110910245.8

(51) Int. Cl. H01L 21/768; H01L 23/528; H01L 21/8234; H01L 29/66

(52) U.S. Cl. CPC H01L 21/76804; H01L 21/76831; H01L 23/528; H01L 21/76877; H01L 21/823475; H01L 29/66787

(57) ABSTRACT

Provided are semiconductor and a method for manufacturing semiconductor. The semiconductor structure includes: a substrate and a gate located on the substrate, a source is formed in the substrate on one side of the gate, and a drain is formed in the substrate on another side of the gate; a dielectric layer covering a surface of the gate; a contact structure passing through the dielectric layer and electrically connected to the source or the drain, the contact structure including a stack of a first contact layer and a second contact layer, and in a direction from the source to the drain, a width of the second contact layer being greater than a width of the first contact layer; and an electrical connection layer located at a top surface of the dielectric layer and in contact with part of a top surface of the second contact layer.

### CROSS-REFERENCE TO RELATED APPLICATIONS

This is a continuation application of International Patent Application No. PCT/CN2022/071855, filed on Jan. 13, 2022, which claims priority to Chinese Patent Application No. 202110910245.8, with an application title of “SEMICONDUCTOR STRUCTURE AND METHOD FOR MANUFACTURING SAME” and filed on Aug. 9, 2021. The disclosures of International Patent Application No. PCT/CN2022/071855 and Chinese Patent Application No. 202110910245.8 are incorporated by reference herein in their entireties.

### TECHNICAL FIELD

Embodiments of the disclosure relate to, but not limited to, a semiconductor structure and a method for manufacturing same.

### BACKGROUND

With the rapid development of integrated circuit technology, the density of devices in an integrated circuit gets higher and higher, the feature size of a semiconductor device is diminishing, and an electrode area of a semiconductor structure is also diminishing. In a manufacturing procedure, for the needs of leads or tests, a metal interconnection structure would be made on the electrode.

Introduction of the metal interconnection structure not only increase device integration and improve a device working speed, but also further reduce chip costs and simplify a device manufacturing process. The metal interconnection structure at least includes a contact structure passing through a dielectric layer and an electrical connection layer located at a top surface of the contact structure. The contact structure and the electrical connection layer play a key role in the metal interconnection structure and directly affect the performance of the semiconductor structure.

However, the prior art has the problem that the electrical connection performance between the contact structure and the electrical connection layer is poor.

### SUMMARY

An aspect of embodiments of the disclosure provides a semiconductor structure, which includes: a substrate and a gate located on the substrate, a dielectric layer, a contact structure and an electrical connection layer. A source is formed in the substrate on one side of the gate, and a drain is formed in the substrate on another side of the gate. The dielectric layer is located on the substrate and covers a surface of the gate. The contact structure passes through the dielectric layer and is electrically connected to the source or the drain. The contact structure includes a stack of a first contact layer and a second contact layer, the first contact layer is higher than a top surface of the gate. In a direction from the source to the drain, a width of the second contact layer is greater than a width of the first contact layer. The electrical connection layer is located at a top surface of the dielectric layer and in contact with a part of a top surface of the second contact layer.

According to some embodiments of the disclosure, another aspect of embodiments of the disclosure further provides a semiconductor structure, which includes: providing a substrate and a gate located on the substrate, in which a source is formed in the substrate on one side of the gate, and a drain is formed in the substrate on another side of the gate; forming a dielectric layer covering a surface of the gate on the substrate; forming, a through hole passing through the dielectric layer and extending to a surface of the source or a surface of the drain, in the dielectric layer, in which the through holes comprises a first through hole and a second through hole in communication with the first through hole, the first through hole is higher than a top surface of the gate and located between the substrate and the second through hole, and in a direction from the source to the drain, a width of the second through hole is greater than a width of the first through hole; forming a contact structure filled into the through holes, with the contact structure passing through the dielectric layer and being electrically connected to the source or the drain, in which the contact structure comprises a first contact layer and a second contact layer, the first contact layer is filled into the first through hole, and the second contact layer is filled into the second through hole; and forming an electrical connection layer at a top surface of the dielectric layer, with the electrical connection layer being in contact with a part of a top surface of the second contact layer.

### BRIEF DESCRIPTION OF THE DRAWINGS

One or more embodiments are exemplified by pictures in accompanying drawings corresponding thereto. These exemplifications do not constitute a limitation for the embodiments. The drawings in the accompanying drawings do not constitute a proportion limitation unless otherwise stated.

FIG. 1 is a schematic section view of a semiconductor structure according to an embodiment of the disclosure.

FIG. 2 is another schematic section view of a semiconductor structure according to an embodiment of the disclosure.

FIG. 3 to FIG. 6 are schematic views of a structure corresponding to the steps of a method for manufacturing a semiconductor structure according to an embodiment of the disclosure.

### DETAILED DESCRIPTION

As can be known from the background art that the prior art has the problem that the electrical connection performance between the contact structure and the electrical connection layer is poor.

It is found that small contact area between the contact structure and the electrical connection layer is one of the reasons causing the poor electrical connection performance between the contact structure and the electrical connection layer. The small contact area results in a larger contact resistance between the contact structure and the electrical connection layer. Moreover, when the electrical connection layer is form with relatively low alignment accuracy, the contact area between the contact structure and the electrical connection layer will be further reduced, which even would cause the problem of disconnection between the electrical connection layer and the contact structure.

The embodiments of the disclosure provide a semiconductor structure. The width of the top of the contact structure is relatively large, i.e., the width of the second contact layer is relatively large. As compared with the contact between the electrical connection layer and the first contact layer with a relatively small width, the area of the contact structure covered by the electrical connection layer is increased, and the contact resistance between the contact structure and the electrical connection layer is reduced. In addition, in the process of forming the electrical connection layer, the disconnection between the electrical connection layer and the contact structure caused by an alignment deviation can further be avoided, and a process window for forming the electrical connection layer is increased.

The following describes each embodiment of the disclosure in detail with reference to the accompanying drawings. However, a person having ordinary skill in the art can understand that in various embodiments of the disclosure, many technical details are presented to make the disclosure better understood by the reader. However, the technical solution claimed in the disclosure may also be achieved without such technical details and various variations and modifications based on the following embodiments.

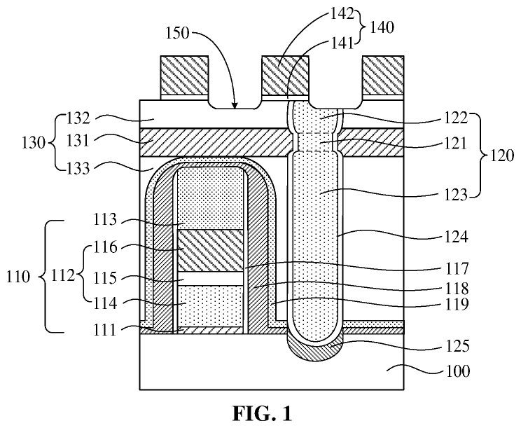

FIG. 1 is a schematic view of a semiconductor structure according to an embodiment of the disclosure.

With reference to FIG. 1, the semiconductor structure includes: a substrate 100, a gate 110 located on the substrate 100, a dielectric layer 130, a contact structure 120 and an electrical connection layer 140. In the substrate 100, a source (not shown) is formed in the substrate on one side of the gate 110, and a drain (not shown) is formed in the substrate on another side of the gate 110. The dielectric layer 130 is located on the substrate 100 and covers a surface of the gate 110. The contact structure 120 passes through the dielectric layer 130 and is electrically connected to the source or the drain. The contact structure 120 includes a first contact layer 121 and a second contact layer 122 stacked on the first contact layer 121. The first contact layer 121 is higher than a top surface of the gate 110. In a direction from the source to the drain, a width of the second contact layer 122 is greater than a width of the first contact layer 121. The electrical connection layer 140 is located at a top surface of the dielectric layer 130 and in contact with a part of a top surface of the second contact layer 122.

The width of the top of the contact structure 120 in a direction from the source to the drain is increased. In this way, the area of the top surface of the contact structure 120 covered by the electrical connection layer 140 is increased, and the contact resistance between the electrical connection layer 140 and the contact structure 120 is reduced, and thus a current conduction capability between the electrical connection layer 140 and the contact structure 120 and the performance of the semiconductor structure are improved. Meanwhile, the disconnection between the electrical connection layer 140 and the contact structure 120 caused by an alignment deviation can be avoided, and a process window for forming the electrical connection layer 140 is enlarged. It should be noted that, if no specific explanations, the width mentioned below all refers to the width in a direction from the source to the drain.

The semiconductor structure may be a memory, for example, a Dynamic Random Access Memory (DRAM), a Static Random-Access Memory (SRAM), or a Synchronous Dynamic Random-Access Memory (SDRAM).

The substrate 100 may be a semiconductor substrate or a silicon substrate on an insulator. In some embodiments, the substrate 100 may be a silicon substrate. In some other embodiments, the substrate 100 may also be a germanium substrate, a silicon germanium substrate, or a silicon carbide substrate.

The gate 110 includes a stack of a gate dielectric layer 111, a gate conductive layer 112 and a gate cover layer 113. In some embodiments, the gate conductive layer 112 may include a stack of a first conductive layer 114, a barrier layer 115 and a second conductive layer 116. The barrier layer 115 may prevent mutual diffusion between the first conductive layer 114 and the second conductive layer 116. The material of the first conductive layer 114 is a semiconductor material, and the material of the second conductive layer 116 is a metal material. In some embodiments, the material of the first conductive layer 114 may be polycrystalline silicon, the material of the barrier layer 115 may be titanium nitride, and the material of the second conductive layer 116 may be tungsten, copper or aluminum.

In some other embodiments, the gate conductive layer 112 may be a single-layer structure, the material of the gate conductive layer 112 may be a semiconductor material or metal. The semiconductor material may be polycrystalline silicon, and the metal may be tungsten, copper or aluminum.

The function of the gate cover layer 113 is mainly an isolation and insulation. The material of the gate cover layer 113 may be silicon oxide or silicon nitride.

The semiconductor structure may also include: a first side wall layer 117 covering a sidewall of the gate 110, a second side wall layer 118 and an etching stop layer 119. The second side wall layer 118 covers the first side wall layer 117, the gate 110 and a part of the substrate 100. The etching stop layer 119 covers the second side wall layer 118.

The source is formed in the substrate 100 on one side of the gate 110, and the drain is formed in the substrate 100 on the other side of the gate 110. The bottom of the contact structure 120 is electrically connected to the source or the drain, and the top surface of the contact structure is connected to the electrical connection layer 140, so that an electrical connection is formed between the source or drain and the electrical connection layer 140. In some embodiments, the semiconductor structure is a PMOS transistor, and thus doping ions of the drain and the source are P-type ions; in some other embodiments, the semiconductor structure is an NMOS transistor, and thus doping ions of the source and drain are N-type ions.

In some embodiments, the dielectric layer 130 may include: a stack of a first dielectric layer 131 and a second dielectric layer 132. The first dielectric layer 131 and the second dielectric layer 132 are both higher than the top surface of the gate 110, and the first contact layer 121 passes through the first dielectric layer 131. The second contact layer 122 passes through the second dielectric layer 132. An orthographic projection of the first contact layer 121 on a surface of the substrate 100 is located within an orthographic projection of the second contact layer 122 on the surface of the substrate 100, and an area of the orthographic projection of the first contact layer 121 on the surface of the substrate 100 is smaller than an area of the orthographic projection of the second contact layer 122 on the surface of the substrate 100.

That is to say, the first contact layer 121 is directly opposite to and contiguous with the second contact layer 122, so that the contact area between the first contact layer 121 and the second contact layer 122 is large, and the contact resistance between the first contact layer 121 and the second contact layer 122 is small. Therefore, the conductive capability of the contact structure 120 is great.

A sectional area of the second contact layer 122 in a direction parallel to the surface of the substrate 100 is greater than a sectional area of the first contact layer 121 in a direction parallel to the surface of the substrate 100. In this way, the depth to width ratio of the contact structure 120 can be reduced. Hence, in the formation of the contact structure 120, slots generated due to excessive depth to width ratio can be reduced, i.e., the hole filling capability of the process for forming the contact structure 120 can be improved, to improve the conductive capability of the contact structure 120.

In some embodiments, a density of a material of the first dielectric layer 131 is greater than a density of a material of the second dielectric layer 132. The first dielectric layer 131 has a function of protecting the gate 110. The density of the material of the first dielectric layer 131 is greater than that of the second dielectric layer, so that the protection effect for the gate 110 is better. The density of the material of the second dielectric layer 132 is smaller than that of the first dielectric layer, so that the etch rate for the second dielectric layer 132 with smaller density would be faster in an actual process. In this way, in one etching process, the width of the through hole formed in the second dielectric layer 132 would be greater than the width of the through hole formed in the first dielectric layer 131. Hence, the structure in which the width of the second contact layer 122 located in the second dielectric layer 132 is greater than the width of the first contact layer 121 located in the first dielectric layer 131, would be easier to be achieved after the contact structure 120 is filled into the through holes.

In some embodiments, by selecting a proper etching process parameter (for example, selecting a proper etching gas), the etch rate for the material of the second dielectric layer 132 would be greater than the etch rate for the material of the first dielectric layer 131. In this way, in one etching process, the width of the through hole formed in the second dielectric layer 132 would be greater than the width of the through hole formed in the first dielectric layer 131. Hence, the structure in which the width of the second contact layer 122 located in the second dielectric layer 132 is greater than the width of the first contact layer 121 located in the first dielectric layer 131, would be easier to be achieved after the contact structure 120 is filled into the through holes.

The material of the first dielectric layer 131 may be silicon oxynitride or silicon nitride; and the material of the second dielectric layer 132 may be silicon oxide.

In some embodiments, a ratio of a thickness of the second dielectric layer 132 to a thickness of the first dielectric layer 131 ranges from 1.1 to 2. In this thickness ratio range, the thickness of the second contact layer 122 in the second dielectric layer 132 is greater than that of the first dielectric layer. In addition, the width of the second contact layer 122 is larger than the first contact layer 121. Therefore, a volume of the second contact layer 122 is larger than the first contact layer 121, and thus, the resistance of the entire contact structure 120 can be further reduced. Furthermore, in this thickness ratio range, the first dielectric layer 131 may also better protect the gate.

In other embodiments, the first contact layer 121 may also be contiguous with the second contact layer 122 in a misalignment manner, i.e., only a part of the top surface of the first contact layer 121 is contiguous with a part of the bottom of the second contact layer 122.

It can be understood that, in other embodiments, the material of the first dielectric layer may also be the same as the material of the second dielectric layer, for example, both be silicon nitride.

The dielectric layer 130 may further include: an intermediate dielectric layer 133 located on the surface of the substrate 100 and covering the sidewall of the gate 110; the first dielectric layer 131 is located at the top surface of the intermediate dielectric layer 133. The contact structure 120 further includes a conductive plug 123 passing through the intermediate dielectric layer 133. An orthographic projection of the first contact layer 121 on the surface of the substrate 100 is located within an orthographic projection of the conductive plug 123 on the surface of the substrate 100. In addition, an area of the orthographic projection of the first contact layer 121 on the surface of the substrate 100 is smaller than an area of the orthographic projection of the conductive plug 123 on the surface of the substrate 100.

That is to say, the conductive plug 123 is directly opposite to and contiguous with the first contact layer 121, so that the contact area between the conductive plug 123 and the first contact layer 121 is relatively large. Hence, the contact resistance between the conductive plug 123 and the first contact layer 121 is relatively small, and therefore, the resistance of the contact structure 120 is further reduced.

The width of the conductive plug 123 is greater than the width of the first contact layer 121. That is to say, the volume of the conductive plug 123 is increased as compared to the first contact layer 121, so that the resistance of the contact structure 120 is further reduced, thereby facilitating the current conduction capability of the contact structure 120 and improving the performance of the semiconductor structure.

In addition, in some embodiments, the width of the conductive plug 123 may be equal to the width of the second contact layer 122. In some other embodiments, the width of the conductive plug 123 may also be greater than or smaller than the width of the second contact layer 122.

The intermediate dielectric layer 133, the first dielectric layer 131, and the second dielectric layer 132 are successively stacked. The top surface of the intermediate dielectric layer 133 is flush with the top surface of the etching stop layer 119, and covers the side of the gate 110. In this way, the gate 110 can be insulated from other conductive structures to avoid the generation of electrical interferences. In some other embodiments, the top surface of the intermediate dielectric layer 133 may also be higher than the top surface of the etching stop layer 119.

In some embodiments, the density of the material of the first dielectric layer 131 may be greater than the density of the material of the intermediate dielectric layer 133. The density of the material of the intermediate dielectric layer 133 is relatively small, so that, in an actual process, the etch rate for the intermediate dielectric layer 133 is greater than the etch rate for the first dielectric layer 131. In this way, in a one etching process, the width of the through hole formed in the intermediate dielectric layer 133 would be greater than the width of the through hole formed in the first dielectric layer 131, so that the width of the conductive plug 123 located in the intermediate dielectric layer 133 to be greater than the width of the first contact layer 121 located in the first dielectric layer 131, to reduce the resistance of the entire contact structure 120.

In some embodiments, by selecting a proper etching process parameter (for example, selecting a proper etching gas), the etch rate of the material for the intermediate dielectric layer 133 would be greater than the etch rate for the material of the first dielectric layer 131. In this way, in one etching process, the width of the through hole formed in the intermediate dielectric layer 133 would be greater than the width of the through hole formed in the first dielectric layer 131. Hence, the structure in which the width of the conductive plug 123 located in the intermediate dielectric layer 133 is greater than the width of the first contact layer 121 located in the first dielectric layer 131, would be easier to be achieved after the contact structure 120 is filled into the through holes.

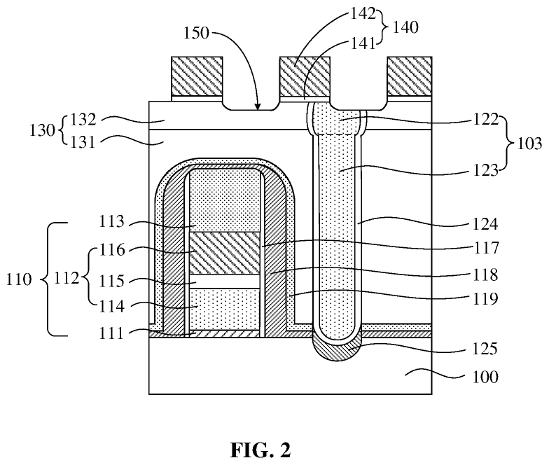

With reference to FIG. 2, in some other embodiments, the material of the first dielectric layer 131 may also be the same as the material of the intermediate dielectric layer 133, i.e., the density of the material of the first dielectric layer 131 is equal to the density of the material of the intermediate dielectric layer 133, and the width of the conductive plug 123 is equal to the width of the first contact layer 121. The density of the first dielectric layer 131 is greater than the density of the material of the second dielectric layer 132, or the etch rate for the material of the second dielectric layer 132 is greater than the etch rate for the material of the first dielectric layer 131, and the width of the second contact layer 122 is greater than the width of the conductive plug 123.

Continuously referring to FIG. 1, in some embodiments, the material of the intermediate dielectric layer 133 may be the same as the material of the second dielectric layer 132. In some other embodiments, the material of the intermediate dielectric layer 133 may also be different from the material of the second dielectric layer 132, for example, the material of the intermediate dielectric layer 133 may be silicon oxynitride, and the material of the second dielectric layer 132 may be silicon nitride.

The thickness of the intermediate dielectric layer 133 may be greater than the thickness of the first dielectric layer 131, and greater than the thickness of the second dielectric layer 132. In this way, the volume ratio of the conductive plug 123, which has a relatively large width and is located in the intermediate dielectric layer 133, in the entire contact structure 120 is relatively large, so as to improve the conductive capability of the entire contact structure 120.

In some other embodiments, the conductive plug 123 may also be contiguous with the first contact layer 121 in a misalignment manner. That is to say, only a part of the top surface of the conductive plug 123 is contiguous with a part of the bottom surface of the first contact layer 121.

The side and bottom of the contact structure 120 may also have a barrier layer 124. Specifically, the material of the contact structure 120 is tungsten; in some other embodiments, the material of the contact structure 120 may also be copper or aluminum. The barrier layer 124 may prevent metal ions in the contact structure 120 from diffusing into the substrate 100 and the dielectric layer 130. In some embodiments, the material of the barrier layer 124 may be titanium nitride; in some other embodiments, the material of the barrier layer 124 may also be at least one of tantalum, titanium, tantalum nitride or titanium nitride.

The bottom of the barrier layer 124 may further be provided with a metal silicide layer 125; the existence of the metal silicide layer 125 may result in a lower contact resistance between the contact structure 120 and the source or drain, to further improve the conductive capability of the contact structure 120. Specifically, the metal silicide layer 125 may be a metal silicide, for example, cobalt silicide.

Part of the bottom of the electrical connection layer 140 is in contact with the dielectric layer 130. The remaining part thereof is in contact of the part of the top surface of the second contact layer 122. A misalignment connection is formed. This arrangement mode enables a greater number of electrical connections layers 140 to be formed in a same area, and at the same time, the top view of the electrical connection layer 140 is a hexagonal close-packed structure, space is fully used, and the performance of the semiconductor structure is improved.

In some embodiments, a part of the top surface of the second contact layer 122 that is not covered by the electrical connection layer 140 is a concave surface 150 recessed toward the substrate 100.

The concave surface 150 further extends to part of the top surface of the dielectric layer 130. The concave surface 150 may separate the electrical connection layer 140 and the second contact layer 122 connected to the electrical connection layer 140 from other conductive structures, to prevent short circuit. To facilitate the control of the etching process easier, the part of the top surface of the second contact layer 122 is thus etched. As can be understood, in some embodiments, the part of the top surface of the second contact layer 122 that is not covered by the electrical connection layer 140 may also be a plane.

In some embodiments, the electrical connection layer 140 may include a stack of a diffusion barrier layer 141 and a conductive layer 142. The diffusion barrier layer 141 covers a part of the top surface of the second contact layer 122.

The material of the conductive layer 142 may be tungsten, copper, or aluminum. The diffusion barrier layer 141 may prevent metal ions in the conductive layer 142 from diffusing into the dielectric layer 130. The material of the diffusion barrier layer 141 may be at least one of titanium nitride, tantalum, titanium, tantalum nitride or titanium nitride.

In the semiconductor structure according to the embodiment above, the second contact layer 122 is stacked on the first contact layer 121, the first contact layer 121 is higher than the top surface of the gate 110, and the width of the second contact layer 122 is greater than the width of the first contact layer 121. That is to say, the top of the contact structure 120 has a relatively large width, and therefore, the area of the top surface of the contact structure 120 that can be covered by the electrical connection layer 140 is also relatively large, so that the contact structure 120 and the electrical connection layer 140 have a relatively small contact resistance. As such, the improvement of the electrical connection performance between the contact structure 120 and the electrical connection layer 140 achieved. On the other hand, since the width of the top of the contact structure 120 is relatively large, there is a relatively large process window in the process of forming the electrical connection layer 140, so as to avoid the problem of an excessively small area of the top surface of the contact structure 120 covered by the electrical connection layer 140 caused by alignment deviation, so as to improve the electrical performance of the semiconductor structure.

Another embodiment of the disclosure provides a method for manufacturing a semiconductor structure. The method for manufacturing a semiconductor structure may form the semiconductor structure according to the above embodiments. The method for manufacturing a semiconductor structure according to the other embodiment of the disclosure is explained in details by combining with the accompanying drawings as follows.

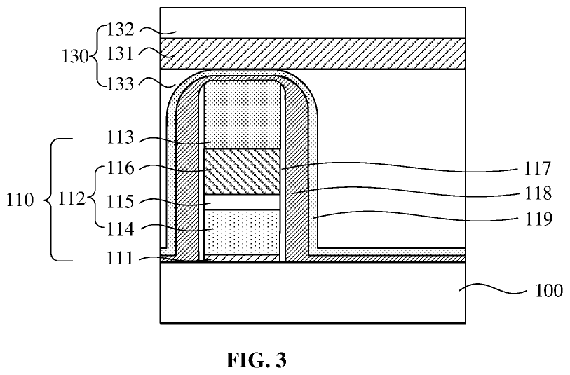

FIG. 3 to FIG. 6 are schematic views of a structure corresponding to each step of a method for manufacturing a semiconductor structure according to another embodiment of the disclosure.

With reference to FIG. 3, a substrate 100 and a gate 110 located on the substrate 100 are provided. The substrate 100 at both sides of the gate 110 has a source or a drain. A dielectric layer 130 is formed on the substrate 100, the dielectric layer 130 covers a surface of the gate 110.

The substrate 100 is a semiconductor substrate. In this embodiment, the semiconductor substrate is a silicon substrate. In some other embodiments, the semiconductor substrate may be a germanium substrate, a silicon germanium substrate or a silicon carbide substrate.

The gate 110 includes a stack of a gate dielectric layer 111, a gate conductive layer 112 and a gate cover layer 113. In some embodiments, the gate conductive layer 112 may include a stack of a first conductive layer 114, a barrier layer 115 and a second conductive layer 116.

The semiconductor structure may also include: a first side wall layer 117 covering a sidewall of the gate 110, a second side wall layer 118 and an etching stop layer 119. The second side wall layer 118 covers the first side wall layer 117, the gate 110 and a part of the substrate 100. The etching stop layer 119 covers the second side wall layer 118.

For the detailed explanations of the substrate and gate, reference can be made to the detailed descriptions of the above embodiments, and the detailed description thereof will be omitted.

The source is formed in the substrate 100 on one side of the gate 110, and the drain is formed in the substrate 100 on the other side of the gate 110. The bottom of the contact structure 120 is electrically connected to the source or the drain, and the top surface of the contact structure is connected to the electrical connection layer 140, so that an electrical connection is formed between the source or drain and the electrical connection layer 140. In some embodiments, the semiconductor structure is a PMOS transistor, and thus doping ions of the drain and the source are P-type ions; in some other embodiments, the semiconductor structure is an NMOS transistor, and thus doping ions of the source and drain are N-type ions.

A process of forming the dielectric layer 130 includes an operation in which a stack of an intermediate dielectric layer 133, a first dielectric layer 131, and a second dielectric layer 132 is formed on the substrate 100, with a top surface of the intermediate dielectric layer 133 being flush with the top surface of the gate 110 or higher than the top surface of the gate 110.

The first dielectric layer 131 covers the top surface of the gate 110. In this way, the first dielectric layer 131 may protect the gate 110 to prevent the gate 110 from being exposed in air due to an excessive etching during the etching of the semiconductor structure, which affects the performance of the semiconductor structure. The top surface of the intermediate dielectric layer 133 is flush with the top surface of the etching stop layer 119, and covers the side of the gate 110. In this way, the gate 110 can be insulated from other conductive structures to avoid the generation of electrical interferences. In some other embodiments, the top surface of the intermediate dielectric layer 133 may also be higher than the top surface of the etching stop layer 119.

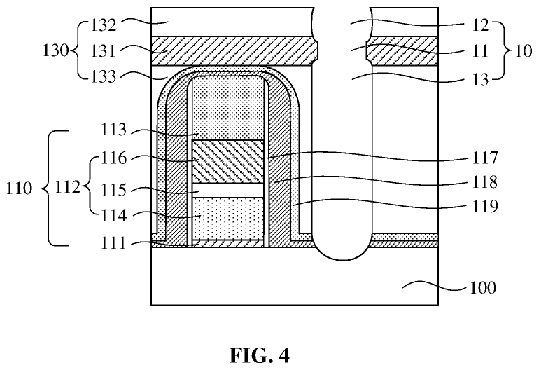

With reference to FIG. 4, a through hole 10 is formed in the dielectric layer 130. The through hole 10 passes through the dielectric layer 130 and extends to a surface of the source or a surface of the drain. The through hole 10 includes a first through hole 11 and a second through hole 12 in communication with the first through hole. The first through hole 11 is higher than a top surface of the gate 110, and is located between the substrate 100 and the second through hole 12. In addition, in a direction from the source to the drain, a width of the second through hole 12 is greater than a width of the first through hole 11.

The width of the second through hole 12 is greater than the width of the first through hole 11. Therefore, in subsequent steps, after the first contact layer filling into the first through hole 11 and the second contact layer 122 filling into the second through hole 12 are formed, the width of the second contact layer 122 is greater than the width of the first contact layer 121.

In some embodiments, the formation of the through holes 10 may include a operation in which the second dielectric layer 132, the first dielectric layer 131 and the intermediate dielectric layer 133 are patterned by an etching process, to form the first through hole 11, the second through hole 12 and a third through hole 13. The first through hole 11 passes through the first dielectric layer 131, the second through hole 12 passes through the second dielectric layer 132, the third through hole 13 passes through the intermediate dielectric layer 133 and extends to a surface of the source or a surface of the drain. An orthographic projection of the first through hole 11 on a surface of the substrate 100 is located within an orthographic projection of the second through hole 12 on the surface of the substrate 100. An area of the orthographic projection of the first through hole 11 on the surface of the substrate 100 is smaller than an area of the orthographic projection of the second through hole 12 on the surface of the substrate 100.

The first through hole 11 is opposite to and contiguous with the second through hole 12. Therefore, in subsequent steps, after the first contact layer 121 is formed in the first through hole 11 and the second contact layer 122 is formed in the second through hole 12, the contact area between the first contact layer 121 and the second contact layer 122 is relatively large, thus the contact resistance between the first contact layer 121 and the second contact layer 122 is relatively small. As such, the current conduction capability of the contact structure 120 is increased. An area of the orthographic projection of the first through hole 11 on the surface of the substrate 100 is smaller than an area of the orthographic projection of the second through hole 12 on the surface of the substrate 100, so that an area of the orthographic projection of the first contact layer 121 on the surface of the substrate 100 is smaller than an area of the orthographic projection of the second contact layer 122 on the surface of the substrate 100, i.e., a sectional area of the second contact layer 122 in a direction parallel to the surface of the substrate is larger that of first contact layer. In addition, the width of the second through hole 12 is larger, so that the depth to width ratio of the through hole 10 is smaller. Therefore, in subsequent operation of forming the contact structure, the slot in the contact structure 120 formed due to the great depth to width ratio can be reduced.

The etch rate for the first dielectric layer 131 is lower than the etch rate for the second dielectric layer 132 in the etching process. In this way, the volume consumption of the first dielectric layer 131 is lower than the volume consumption of the second dielectric layer 132, and thus the width of the formed second through hole 12 is greater than the width of the formed first through hole 11.

The density of the material of the first dielectric layer 131 is greater than the density of the material of the second dielectric layer 132. The density of the first dielectric layer 131 is larger, so that it can better protect the gate 110. The density of the material of the second dielectric layer 132 is relatively small, so that, in the etching process, the etch rate for the second dielectric layer 132 is greater than the etch rate for the first dielectric layer 131.

Specifically, the material of the first dielectric layer 131 includes silicon oxynitride or silicon nitride; and the material of the second dielectric layer 132 includes silicon oxide.

As can be understood, in some other embodiments, different etching processes can also be adopted for the first dielectric layer 131 and the second dielectric layer 132. Moreover, the etch rate for the first dielectric layer 131 is lower than the etch rate for the second dielectric layer 132 in the etching process. In this way, the same material may also be adopted as the materials of both of the first dielectric layer 131 and the second dielectric layer 132.

In some embodiments, the etch rate for the first dielectric layer 131 is lower than the etch rate for the intermediate dielectric layer 133 in the etching process. An orthographic projection of the first through hole 11 on the surface of the substrate 100 is located within an orthographic projection of the third through hole 13 on the surface of the substrate 100. An area of the orthographic projection of the first through hole 11 on the surface of the substrate 100 is smaller than an area of the orthographic projection of the third through hole 13 on the surface of the substrate 100.

In this embodiment, the first through hole 11 is directly opposite to and contiguous with the third through hole 13. Therefore, in subsequent steps, after the first contact layer 121 is formed in the first through hole 11 and the conductive plug 123 is formed in the third through hole 13, the contact area between the first contact layer 121 and the conductive plug 123 is relatively large, so as to enhance the current conduction capability of the entire contact structure 120.

In some embodiments, the density of the material of the first dielectric layer 131 is greater than the density of the material of the intermediate dielectric layer 133. In this embodiment, the density of the material of the intermediate dielectric layer 133 is equal to the density of the material of the second dielectric layer 132, so that the width of the third through hole 13 may be equal to the width of the second through hole 12.

As can be understood, in some embodiments, the density of the material of the intermediate dielectric layer 133 may also be lower than the density of the material of the second dielectric layer 132, so that the width of the third through hole 13 may be smaller than the width of the second through hole 12. In some other embodiments, the density of the material of the intermediate dielectric layer 133 may also be greater than the density of the material of the second dielectric layer 132, so that the width of the third through hole 13 may be greater than the width of the second through hole 12.

Specifically, in some embodiments, in the same etching operation, a same etching process parameter is adopted to form the first through hole 11, the second through hole 12, and the third through hole 13. In this way, by one single etching operation, the first through hole 11 having the width smaller than the width of the second through hole 12 and the width of the third through hole 13 can be formed, so as to simplify the process procedure, for ease of scale production.

As can be understood, in some other embodiments, different etching processes can be adopted for the second dielectric layer 132, the first dielectric layer 131 and the intermediate dielectric layer 133.

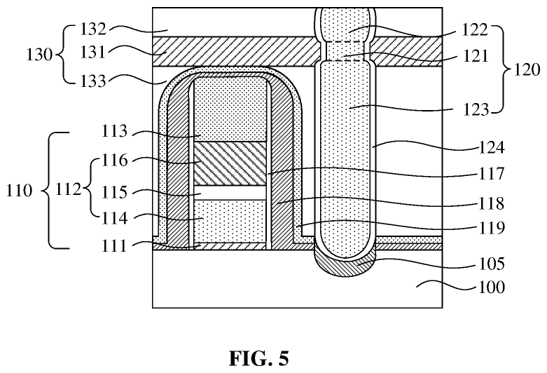

With reference to FIG. 5, a contact structure 120 filled into the through holes 10 (referring to FIG. 4) is formed, the contact structure 120 passes through the dielectric layer 130 and is electrically connected to the source or the drain. The contact structure 120 includes a first contact layer 121 and a second contact layer 122. The first contact layer 121 is filled into the first through hole 11 (referring to FIG. 4), and the second contact layer 122 is filled into the second through hole 12 (referring to FIG. 4).

The contact structure 120 filled into the through hole 10 (referring to FIG. 4) is formed by a deposition process. In some embodiments, the formation of the contact structure 120 includes an operation in which a conductive film filled into the first through hole 11, second through hole 12 and third through hole 13 is formed, and the conductive film being located at the top surface of the second dielectric layer 132; in which a part of the conductive film higher than the top surface of the second dielectric layer 132 is removed, the remainder of the conductive film located in the through hole 10 forms the contact structure 120.

The width of the second through hole 12 is greater than the width of the first through hole 11, and therefore, as compared with the configuration where the width of the second through hole 12 is equal to the width of the first through hole 11, the depth to width ratio of the through hole 10 is reduced. In this way, problems such as premature closing of the conductive film can be avoided when the conductive film is formed in the through hole 10, so as to reduce the slot in the contact structure 120 formed due to the high depth to width ratio.

Before the formation of the contact structure 120, it further includes an operation in which the barrier layer 124 is formed at the side and bottom of the contact structure 120. The barrier layer 124 covers the sidewall and bottom wall of the through hole 10 (referring to FIG. 4). Specifically, the material of the contact structure 120 is tungsten. In some other embodiments, the material of the contact structure 120 may also be copper or aluminum. The material of the barrier layer 124 may be titanium nitride. In some further embodiments, the material of the barrier layer 124 may also be at least one of tantalum, titanium, tantalum nitride or titanium nitride.

The width of the second contact layer 122 is greater than the width of the first contact layer 121. On one hand, the width of the second contact layer 122 is relatively large, so that the resistance of the entire contact structure 120 is relatively small On the other hand, when the second contact layer 122 is subsequently connected to the electrical connection layer, the contact area with the electrical connection layer 140 can be increased, so as to reduce the contact resistance between the electrical connection layer 140 and the second contact layer 122, thereby improving the current conduction capability of the contact structure 120 and the performance of the semiconductor structure.

The conductive plug 123 is directly opposite to and contiguous with the first contact layer 121, so that the contact area between the conductive plug 123 and the first contact layer 121 is relatively large. As such, the contact resistance between the conductive plug 123 and the first contact layer 121 is relatively small. In some other embodiments, the conductive plug may also be contiguous with the first contact layer in a misalignment manner.

The width of the conductive plug 123 is greater than the width of the first contact layer 121. Hence, the volume of the conductive plug 123 is increased, the resistance thereof is reduced, which facilitates the improvement of the current conduction capability of the contact structure 120.

In some embodiments, the width of the conductive plug 123 is equal to the width of the second contact layer 122. In some other embodiments, the width of the conductive plug 123 may also be greater than the width of the second contact layer 122. In some other embodiments, the width of the conductive plug 123 may also be smaller than the width of the second contact layer 122.

In some embodiments, before the contact structure 120 is formed, a metal silicide layer 125 may also be formed at the bottom of the through hole 10 (referring to FIG. 4). The metal silicide layer 125 may reduce the contact resistance between the contact structure 120 and the source or drain. Specifically, the material of the metal silicide layer 125 may be cobalt silicide.

With reference to FIG. 1, an electrical connection layer 140 is formed at the top surface of the dielectric layer 130, and the electrical connection layer 140 is in contact with a part of the top surface of the second contact layer 122.

The electrical connection layer 140 is in contact with the second contact layer 122, and transfers a current flowing from the source or drain to the contact structure 120 to other conductive structures through the electrical connection layer 140, to form electrical connection.

The electrical connection layer 140 includes a diffusion barrier layer 141 and a conductive layer 142 successively formed at the top surface of the dielectric layer 130; a part of the bottom of the diffusion barrier layer 141 is in contact with a part of the top surface of the second contact layer 122. The width of the second contact layer 122 is increased as compared with the width of the first contact layer 121, and therefore, the contact area between the diffusion barrier layer 141 and the top of the contact structure 120 is relatively large. As such, the contact resistance between the electrical connection layer 140 and the second contact layer 122 is relatively small, which facilitates the improvement of the current conduction capability.

The part of the top surface of the second contact layer 122 that is not covered by the electrical connection layer 140 is a concave surface 150 recessed toward the substrate 100. The concave surface 150 may separate the electrical connection layer 140 and the second contact layer 122 connected thereto from other conductive structures, to prevent short circuit. As can be understood, in some embodiments, the part of the top surface of the second contact layer 122 that is not covered by the electrical connection layer 140 may also be a plane.

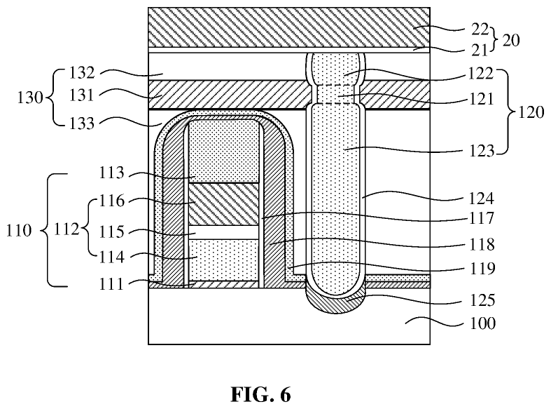

In some embodiments, with reference to FIG. 6, the formation of the electrical connection layer 140 includes an operation in which an initial electrical connection layer 20 covering the top surface of the second contact layer 122 is deposited on the top surface of the dielectric layer 130; a part of the initial electrical connection layer 20 is etched until a part of the top surface of the second contact layer 122 is exposed to form the electrical connection layer 140, and the exposed part of the top surface of the second contact layer 122 is etched in such a way that the part of the top surface of the second contact layer 122 that is not covered by the electrical connection layer 140 forms a concave surface 150 recessed toward the substrate 100.

Before the etching of the part of the initial electrical connection layer 20, it further includes an operation in which a patterned mask layer is formed on the surface of the electrical connection layer 20 to form a mask, a part of the initial electrical connection layer 20 is etched until a part of the top surface of the second contact layer 122 and a part of the top surface of the dielectric layer 130 that is not in contact with the initial electrical connection layer 20 are exposed. The existence of the part of the top surface of the dielectric layer 130 that is not in contact with the initial electrical connection layer 20 separates the formed electrical connection layer 140 from another adjacent electrical connection layer, to prevent electrical interference. It should be noted that even if the etching process may have the alignment deviation, the electrical connection layer 140 formed by etching can still cover the part of the surface of the second contact layer 122 since the width of the second contact layer 122 is relatively large. In other words, the alignment accuracy of the mask required for forming the electrical connection layer 140 can be reduced.

The etching process may also continuously etch the exposed part of the top surface of the second contact layer 122 and the exposed part of the top surface of the dielectric layer 130, to form the concave surface 150. In this way, the electrical connection layer 140 can still be insulated from another adjacent electrical connection layer while the required etching accuracy is further reduced.

As can be understood, in some other embodiments, the etching process may not continuously etch the exposed part of the top surface of the second contact layer 122 and the exposed part of the top surface of the dielectric layer 130, so that the top surface of the second contact layer 122 that is not covered by the electrical connection layer 140 may be a plane.

The specific process of forming the initial electrical connection layer 20 includes: depositing an initial diffusion barrier layer 21 on the surface of the dielectric layer, the initial diffusion barrier layer 21 covering the surface of the entire dielectric layer 130; depositing an initial conductive layer 22 on the entire surface of the initial diffusion barrier layer 21.

In the method for manufacturing a semiconductor structure according to the embodiment above, during performing the etching process on the stack of the intermediate dielectric layer 133, the first dielectric layer 131 and the second dielectric layer 132, the etch rate for the second dielectric layer 132 is greater than the etch rate for the first dielectric layer 131, so that the width of the second through hole 12 formed in the second dielectric layer 132 is greater than the width of the first through hole 11 formed in the first dielectric layer 131. Hence, the width of the second contact layer 122 filled in the second through hole 12 is greater than the width of the first contact layer 121 filled in the first through hole 11. That is to say, the top of the contact structure 120 has a relatively large width, and therefore, the area of the top surface of the contact structure 120 that can be covered by the electrical connection layer 140 is also relatively large. Therefore, the contact structure 120 and the electrical connection layer 140 have a relatively small contact resistance, which facilitates the improvement of the electrical connection performance between the contact structure 120 and the electrical connection layer 140. On the other hand, since the width of the top of the contact structure 120 is relatively large, there is a relatively large process window in the process of forming the electrical connection layer 140, so as to avoid the problem of an excessively small area of the top surface of the contact structure 120 covered by the electrical connection layer 140 caused by alignment deviation, so as to improve the electrical performance of the semiconductor structure.

A person having ordinary technical skill in the art can understand that the various implementations above are specific embodiments for implementing the disclosure, and in practical applications, they can be changed in form and detail without deviating from the spirit and scope of the disclosure. Any person skilled in the art can make various changes and modifications without departing from the spirit and scope of the disclosure. Therefore, the protection scope of the disclosure should be subject to the scope defined by the claims.

1. A semiconductor structure, comprising:
a substrate and a gate located on the substrate, a source is formed in the substrate on one side of the gate, and a drain is formed in the substrate on another side of the gate;
a dielectric layer, located on the substrate and covering a surface of the gate;
a contact structure, passing through the dielectric layer and electrically connected to the source or the drain, the contact structure comprises a stack of a first contact layer and a second contact layer, the first contact layer is higher than a top surface of the gate, and in a direction from the source to the drain, a width of the second contact layer is greater than a width of the first contact layer; and
an electrical connection layer, located at a top surface of the dielectric layer and in contact with a part of a top surface of the second contact layer.

2. The semiconductor structure of claim 1, wherein the dielectric layer comprises a stack of a first dielectric layer and a second dielectric layer, the first dielectric layer and the second dielectric layer are both higher than the top surface of the gate, and the first contact layer passes through the first dielectric layer; the second contact layer passes through the second dielectric layer, an orthographic projection of the first contact layer on a surface of the substrate is located within an orthographic projection of the second contact layer on the surface of the substrate, and an area of the orthographic projection of the first contact layer on the surface of the substrate is smaller than an area of the orthographic projection of the second contact layer on the surface of the substrate.

3. The semiconductor structure of claim 2, wherein a density of a material of the first dielectric layer is greater than a density of a material of the second dielectric layer.

4. The semiconductor structure of claim 3, wherein the material of the first dielectric layer comprises silicon oxynitride or silicon nitride; and the material of the second dielectric layer comprises silicon oxide.

5. The semiconductor structure of claim 2, wherein a ratio of a thickness of the second dielectric layer to a thickness of the first dielectric layer ranges from 1.1 to 2.

6. The semiconductor structure of claim 2, wherein the dielectric layer further comprises an intermediate dielectric layer located on the surface of the substrate and covering a sidewall of the gate, and the first dielectric layer is located at a top surface of the intermediate dielectric layer; and
the contact structure further comprises a conductive plug passing through the intermediate dielectric layer, an orthographic projection of the first contact layer on the surface of the substrate is located within an orthographic projection of the conductive plug on the surface of the substrate, and an area of the orthographic projection of the first contact layer on the surface of the substrate is smaller than an area of the orthographic projection of the conductive plug on the surface of the substrate.

7. The semiconductor structure of claim 6, wherein a density of a material of the first dielectric layer is greater than a density of a material of the intermediate dielectric layer.

8. The semiconductor structure of claim 6, wherein the material of the intermediate dielectric layer is the same as the material of the second dielectric layer.

9. The semiconductor structure of claim 1, wherein a part of the top surface of the second contact layer that is not covered by the electrical connection layer is a concave surface recessed toward the substrate.

10. A method for manufacturing a semiconductor structure, comprising:
providing a substrate and a gate located on the substrate, wherein a source is formed in the substrate on one side of the gate, and a drain is formed in the substrate on another side of the gate;
forming a dielectric layer covering a surface of the gate on the substrate;
forming, a through hole passing through the dielectric layer and extending to a surface of the source or a surface of the drain, in the dielectric layer, wherein the through holes comprises a first through hole and a second through hole in communication with the first through hole, the first through hole is higher than a top surface of the gate and located between the substrate and the second through hole, and in a direction from the source to the drain, a width of the second through hole is greater than a width of the first through hole;
forming a contact structure filled into the through holes, with the contact structure passing through the dielectric layer and being electrically connected to the source or the drain, wherein the contact structure comprises a first contact layer and a second contact layer, the first contact layer is filled into the first through hole, and the second contact layer is filled into the second through hole; and
forming an electrical connection layer at a top surface of the dielectric layer, with the electrical connection layer being in contact with a part of a top surface of the second contact layer.

11. The method for manufacturing a semiconductor structure of claim 10, wherein the forming the dielectric layer comprises: forming a stack of an intermediate dielectric layer, a first dielectric layer and a second dielectric layer on the substrate, with a top surface of the intermediate dielectric layer being flush with the top surface of the gate or higher than the top surface of the gate; and
the forming the through hole comprises: patterning the second dielectric layer, the first dielectric layer and the intermediate dielectric layer by an etching process, to form the first through hole, the second through hole and a third through hole in communication with one another, wherein the first through hole passes through the first dielectric layer, the second through hole passes through the second dielectric layer, the third through hole passes through the intermediate dielectric layer and extends to a surface of the source or a surface of the drain, an orthographic projection of the first through hole on a surface of the substrate is located within an orthographic projection of the second through hole on the surface of the substrate, and an area of the orthographic projection of the first through hole on the surface of the substrate is smaller than an area of the orthographic projection of the second through hole on the surface of the substrate.

12. The method for manufacturing a semiconductor structure of claim 11, wherein an etch rate for the first dielectric layer is lower than an etch rate for the second dielectric layer in the etching process.

13. The method for manufacturing a semiconductor structure of claim 12, wherein a density of the first dielectric layer is greater than a density of the second dielectric layer; and in one same etching process, same etching process parameters are adopted for forming the first through hole, the second through hole and the third through hole.

14. The method for manufacturing a semiconductor structure of claim 11, wherein an etch rate for the first dielectric layer is smaller than an etch rate for the intermediate dielectric layer in the etching process, an orthographic projection of the first through hole on the surface of the substrate is located within an orthographic projection of the third through hole on the surface of the substrate, and an area of the orthographic projection of the first through hole on the surface of the substrate is smaller than an area of the orthographic projection of the third through hole on the surface of the substrate.

15. The method for manufacturing a semiconductor structure of claim 10, wherein the forming the electrical connection layer comprises:
depositing, an initial electrical connection layer covering a top surface of the second contact layer, at a top surface of the dielectric layer; and
etching a part of the initial electrical connection layer until a part of the top surface of the second contact layer is exposed to form the electrical connection layer, and further etching the exposed part of the top surface of the second contact layer, with the top surface of the second contact layer that is not covered by the electrical connection layer forming a concave surface recessed toward the substrate.
